(19) United States
(12) Patent Application Publication
(10) Pub. No.: US 2024/0038491 A1
(43) Pub. Date: Feb. 1, 2024

(54) Ion implantation device with an energy filter and a support element for overlapping at least part of the energy filter

(71) Applicant: mi2-factory GmbH, Jena (DE)

(72) Inventors: Constantin Csato, Jena (DE); Florian Krippendorf, Jena (DE)

(21) Appl. No.: 18/266,511

(22) PCT Filed: Dec. 7, 2021
(86) PCT No.: PCT/EP2021/084474

§ 371 Date: Jun. 9, 2023

(30) Foreign Application Priority Data
Dec. 17, 2020 (LU) LU102300

(51) Int. Cl. H01J 37/317; H01J 37/30; C23C 14/48

(52) U.S. Cl. CPC H01J 37/3171; H01J 37/3007; C23C 14/48

(57) ABSTRACT

An ion implantation device (20) is provided comprising an energy filter (25) with at least one filter layer (32) and at least one support element (30) for supporting the energy filter (25), wherein the at least one support element (30) overlaps at least part of the energy filter (25).

### CROSS-REFERENCE TO RELATED APPLICATIONS

This application is a National Phase entry of PCT Application No. PCT/EP2021/084474 filed on 7 Dec. 2021 which claims priority of Luxemburg Patent Application LU102300 which was filed on 17 Dec. 2020. The entire disclosures of the foregoing patent applications are hereby incorporated herein by reference.

### BACKGROUND OF THE INVENTION

### Field of the Invention

The invention relates to an ion implantation device comprising an energy filter and a support element overlapping the energy filter. The invention relates also to an ion implantation device comprising a first energy filter and a second energy filter with different orientations and a support element overlapping the first and second energy filters. The invention further relates to methods for manufacturing such implantation devices.

### Brief Description of the Related Art

Ion implantation is a method to achieve doping or production of defect profiles in a material, such as semiconductor material or an optical material, with predefined depth profiles in the depth range of a few nanometers to several tens of micrometers. Examples of such semiconductor materials include, but are not limited to silicon, silicon carbide, and gallium nitride. Examples of such optical materials include, but are not limited to, LiNbO₃, glass and PMMA.

There is a need to produce depth profiles by ion implantation which have a wider depth distribution than that of a doping concentration peak or defect concentration peak obtainable by monoenergetic ion irradiation, or to produce doping or defect depth profiles which cannot be produced by one or a few simple monoenergetic implantations. The doping concentration peak can often be described approximately by a Gauss distribution or more precisely by a Pearson distribution. However, there are also deviations from such distributions, especially when so-called channeling effects are present in crystalline material. Prior art methods are known for producing the depth profile use a structured energy filter in which the energy of a monoenergetic ion beam is modified as the monoenergetic ion beam passes through a micro-structured energy filter component. The resulting energy distribution leads to a creation of the depth profile ions in the target material. This is described, for example, in European Patent Nr. 014 516 B1 (Bartko).

An example of such an ion implantation device 20 is shown in FIG. 1 in which an ion beam 10 impacts a structured energy filter 25. The ion beam source 5 could also be a cyclotron, a rf-linear accelerator, an electrostatic tandem accelerator or a single-ended-electrostatic accelerator. In other aspects, the energy of the ion beam source 5 is between 0.5 and 3.0 MeV/nucleon or preferably between 1.0 and 2.0 MeV/nucleon. In one specific embodiment, the ion beam source produces an ion beam 10 with an energy of between 1.3 and 1.7 MeV/nucleon. The total energy of the ion beam 10 is between 1 and 50 MeV, in one preferred aspect, between 4 and 40 MeV, and in a preferred aspect between 8 and 30 MeV. The frequency of the ion beam 10 could be between 1 Hz and 2kH, for example between 3 Hz and 500 Hz and, in one aspect, between 7 Hz and 200 Hz. The ion beam 10 could also be a continuous ion beam Examples of the ions in the ion beam 10 include, but are not limited to aluminum, nitrogen, hydrogen, helium, boron, phosphorous, carbon, arsenic, and vanadium.

In FIG. 1 it will be seen that the energy filter 25 is made from a membrane having a triangular cross-sectional form on the right-hand side, but this type of cross-sectional form is not limiting of the invention and other cross-sectional forms could be used. The upper ion beam 10-1 passes through the energy filter 25 with little reduction in energy because the area 25 min through which the upper ion beam 10-1 passes through the energy filter 25 is a minimum thickness of the membrane in the energy filter 25. In other words, if the energy of the upper ion beam 10-1 on the left-hand side is E1 then the energy of the upper ion beam 10-1 will have substantially the same value E1 on the right-hand side (with only a small energy loss due stopping power of the membrane which leads to absorption of at least some of the energy of the ion beam 10 in the membrane).

On the other hand, the lower ion beam 10-2 passes through an area 25ₘₐₓ in which the membrane of the energy filter 25 is at its thickest. The energy E2 of the lower ion beam 10-2 on the left-hand side is absorbed substantially by the energy filter 25 and thus the energy of the lower ion beam 10-2 on the right-hand side is reduced and is lower than the energy of the upper ion beam, i.e., E1>E2. The result is that the more energetic upper ion beam 10-1 is able to penetrate a greater depth in the substrate material 30 than the less energetic lower ion beam 10-2. This results in a differential depth profile in the substrate material 30, which is part of a wafer.

This depth profile is shown on the right-hand side of the FIG. 1. The solid rectangular area shows that the ions penetrate the substrate material at a depth between d1 and d2. However, the horizontal profile shape is a special case, which is, for example, obtained if all energies are geometrically equally considered and if the material of the energy filter and the substrate is the same. The Gaussian curve shows the approximate depth profile without an energy filter 25 and having a maximum value at a depth of d3. It will be appreciated that the depth d3 is larger than the depth d2 since some of the energy of the ion beam 10-1 is absorbed in the energy filter 25.

In the prior art there are a number of principles known for the fabrication of the energy filter 25. Typically, the energy filter 25 will be made from bulk material with the surface of the energy filter 25 etched to produce the desired pattern, such as the triangular cross-sectional pattern known from FIG. 1. In German Patent No DE 10 2016 106 119 B4 (Csato/Krippendorf) an energy filter was described which was manufactured from layers of materials which had different ion beam energy reduction characteristics. The depth profile resulting from the energy filter described in the Csato/Krippendorf patent application depends on the structure of the layers of the material as well as on the structure of the surface.

A further construction principle is shown in the Applicant's co-pending application DE 2019 120 623.5, in which the energy filter comprises spaced micro-structured layers which are connected together by vertical walls.

The maximum power from the ion beam 10 that can be absorbed through the energy filter 25 depends on three factors: the effective cooling mechanism of the energy filter 25; the thermo-mechanical properties of the membrane from which the energy filter 25 is made, as well as the choice of material from which the energy filter 25 is made. In a typical ion implantation process around 50% of the power is absorbed in the energy filter 25, but this can rise to 80% depending on the process conditions and filter geometry.

An example of the energy filter is shown in FIG. 2 in which the energy filter 25 is made of a triangular structured membrane mounted in a frame 27. In one non-limiting example, the energy filter 25 can be made from a single piece of material, for example, silicon on insulator which comprises an insulating layer silicon dioxide layer 22 having, for example a thickness of 0.2-1 μm sandwiched between a silicon layer 21 (of typical thickness between 2 and 20 μm, but up to 200 μm) and bulk silicon 23 (around 400 μm thick). The structured membrane is made, for example, from silicon, but could also be made from silicon carbide or another silicon-based or carbon-based material or a ceramic.

In order to optimize the wafer throughput in the ion implantation process for a given ion current for the ion beam 10 and thus use the ion beam 10 efficiently, it is preferred to only irradiate the membrane of the energy filter 25 and not the frame 27 in which the membrane is held in place. In reality, it is likely that at least part of the frame 27 will also be irradiated by the ion beam 10 and thus heat up. It is indeed possible that the frame 27 is completely irradiated. The membrane forming the energy filter 25 is heated up but has a very low thermal conductivity as the membrane is thin (i.e., between 21 μm and 20 μm, but up to 200 μm). The membranes are between 2×2 cm² and 35×35 cm² in size and correspond to the size of the target wafers. There is little thermal conduction between the membranes and the frame 27. Thus, the monolithic frame 27 does not contribute to the cooling of the membrane and the only cooling mechanism for the membrane which is relevant is the thermal radiation from the membrane.

The localized heating of the membrane in the energy filter 25 results in addition to thermal stress between the heated parts of the membrane forming the energy filter 25 and the frame. Furthermore, the localized heating of the membrane due to absorption of energy from the ion beam 10 in only parts of the membrane, e.g., due to electrostatic or mechanical scan of the beam or mechanical motion of the filter relative to the beam, also results in thermal stress within the membrane and can lead to mechanical deformation or damage to the membrane. The heating of the membrane also occurs within a very short period of time, i.e., less than a second and often in the order of milliseconds. The cooling effect occurs during or shortly after a local instantaneous irradiation, because adjacent or more distant areas of the filter have a lower temperature than the instantaneously irradiated areas. The problem is that there is practically no heat conduction to provide heat equalization. This inhomogeneous temperature distribution is particularly noticeable for pulsed ion beams 10 and scanned ion beams 10. These temperature gradients can lead to defects and formation of separate phases within the material from which the membrane of the energy filter 25 is made, and even to unexpected modification of the material.

In the past the issue was that in all process phases of ion implantation (i.e. the time before irradiation, the phase of heating the membrane (local or global) by the ion beam, the actual irradiation (local or global), the cooling phase after removal of the ion beam (local or global) and the termination of the implantation process) tensions and the associated risk of membrane damage due to cracking, increased brittleness, etc. may occur more frequently.

Further examples of prior art solutions can be found in US 2019/1 228 50 A1 and/or Csato/Constantin et al.: “Energy filter for tailoring depth profiles in semiconductor doping application”.

Therefore, it is an object of the present invention to provide an implantation device with an energy filter to be more resistant against stresses generated thermomechanically or by formation of mixed phases and defect clusters, i.e., cracks and distortions are better absorbed, or similar issues during the process phases. The aforementioned term “process phases” includes but is not limited to the time before irradiation (i.e. this refers primarily to the handling, transport, installation etc. of the filters), the phase of heating the membrane (locally or globally) by the ion beam, the actual irradiation (locally or globally) of the membrane, the cooling phase after removal of the ion beam (local or global) and the end of the implantation process.

Therefore, there is a need to improve the energy filter of the implantation device to improve the mechanical stability and thermomechanical stability of the energy filter.

### SUMMARY OF THE INVENTION

According to a first aspect of the invention, an implantation device is provided comprising an energy filter with at least one filter layer and at least one support element for supporting the energy filter, wherein the at least one support element overlaps at least part of the energy filter. The at least one support element has a first height and the energy filter has a maximal height, wherein the first height of the at least one support element is at least the same as the maximal height of the energy filter. The at least one support element has a first width and the energy filter has a minimal width, wherein the minimal width of the energy filter is provided as a plateau and is the technological minimum width of the energy filter, wherein the first width of the at least one support element is at least the same as the minimal width of the energy filter.

In one aspect of the ion implantation device, the at least one support element is a rear support element.

In one aspect of the ion implantation device, the at least one support element is a front support element.

In one aspect of the ion implantation device, the minimal width of the energy filter is +/−0,3 μm, +/−0,5 μm, or +/−0,8 μm. The first width of the at least one support element is at least 10%, 20% or 50% larger than the minimal width dₘᵢₙ of the energy filter. The minimal width dₘᵢₙ of the energy filter refers to the technologically required minimum distance between two structural energy filter elements at the thickest point. The first width of the at least one support element is at least two, five or ten times larger than the minimal width dₘᵢₙ of the energy filter.

In one aspect of the ion implantation device, the at least one support element is made of silicon carbide. The at least one support element could also be made of the same material as the energy filter or the at least one support element could be made of a different material as the energy filter.

According to a second aspect of the invention, an implantation device is provided comprising a first energy filter, a second energy filter, and at least one support element. The first energy filter has a first orientation. The second energy filter has a second orientation. The at least one support element for supporting the first and second energy filter overlaps at least part of the first energy filter and at least part of the second energy filter, wherein the first orientation of the first energy filter is different from the second orientation of the second energy filter.

In one aspect of the ion implantation device, the first energy filter and the second energy filter are arranged in one of a square composite arrangement, a rectangular composite arrangement, a hexagonal composite arrangement or a cross-network composite arrangement.

In one aspect of the ion implantation device, the at least one support element has an absorption capacity equal or greater than the maximum absorption capacity of the energy filters.

The support element of a fully transparent energy filter will add discrete peaks to a preferred smooth (continuous) profile. In any case, if the primary energy is high enough, the supporting element also contributes to the resulting depth profile in the substrate. This contribution consists of a discrete energy, which contributes to the total dose of the profile according to the area fraction on the energy filter.

According to a third aspect of the invention, a method for manufacturing an ion implantation device is provided comprising the steps of: Providing an energy filter with at least one filter layer; Providing at least one support element; Supporting the energy filter by the at least one support element; and overlapping at least part of the energy filter by the at least one support element.

According to a fourth aspect of the invention, a method for manufacturing an ion implantation device is provided comprising the steps of: Providing a first energy filter; Orientating the first energy filter in a first orientation; Providing a second energy filter; Orientating the second energy filter in a second orientation different to the first orientation of the first energy filter; Supporting the first and second energy filters by the at least one support element; and overlapping at least part of the energy filters by the at least one support element.

In a further aspect, the method for manufacturing an ion implantation device of the third or fourth aspect can be used in one of a screen printing, multi-layer process, patterning process and etching process sequence.

According to a fifth aspect of the invention, a method for manufacturing an ion implantation device is provided comprising the steps of: Providing a silicon-on-insulator (SOI) wafer as a substrate material having a first surface and a second surface, wherein the thickness of a buried oxide (BOX) varies between 30 nm and 1.5 μm thickness; Applying a first masking material layer and a second masking material layer for masking wet chemical potassium hydroxide (KOH) etching or tetramethylammonium hydroxide (TMAH) etching to the first surface and the second surface of the SOI wafer; Patterning the first masking material layer and the second masking material layer on the first surface and the second surface by using a first and second lithography process step and at least one wet or dry etching patterning step; Cleaning of the first and second surfaces after patterning of the masking material layers; First wet chemical etching of the first or second surfaces using KOH or TMAH etchant; Second wet chemical etching of the first or the second surface using KOH or TMAH etchant; Wet chemical etching of the first or the second surface such that etching is stopped on the BOX layer; Removing of the BOX layer; and removing of the masking layers on the first and second surfaces.

In one aspect of the method, a first protective layer is applied to the first surface or the second surface to prevent etching.

In one further aspect of the method, a second protective layer is applied to the first or the second surface to prevent etching of the first or the second surface.

According to a sixth aspect of the invention, a method for manufacturing an ion implantation device is provided comprising the steps of: Providing a volume material slab, wherein the thickness of the volume material slab is at least the height of at least one support element; and Sequentially removing of the material by a laser etching or mechanical erosive device, wherein the removing is incremental several 1 Onm up to several micrometer per step and involves several removal steps for a given structure, and wherein the sequentially removing is performed according to a predefined 3-D layout of an energy filter structure and the at least one support element.

According to a seventh aspect of the invention, a method for manufacturing an ion implantation device is provided comprising the steps of: Providing a substrate or base layer; Depositing a first support layer and a first filter layer; Patterning the first support layer and the first filter layer using suitable etching techniques like masked etching or sequential etching by a laser or ion beam etching device; Depositing and patterning sequentially and the filter layers; and removing, grinding or etching the substrate or base layer to a desired substrate layer thickness or base layer thickness.

According to an eighth aspect of the invention, a method for manufacturing an ion implantation device is provided comprising the steps of: Providing an energy filter and a separate structure of at least one support element; and applying a bonding layer or gluing layer to achieve a permanent, thermomechanically stable connection between the energy filter and the at least one support element.

### BRIEF DESCRIPTION OF THE FIGURES

The invention will now be described on the basis of figures. It will be understood that the embodiments and aspects of the invention described in the figures are only examples and do not limit the protective scope of the claims in any way. The invention is defined by the claims and their equivalents. It will be understood that features of one aspect or embodiment of the invention can be combined with a feature of a different aspect or aspects of other embodiments of the invention. This invention becomes more obvious when reading the following detailed descriptions of some examples as part of the disclosure under consideration of the enclosed drawings, in which:

FIG. 1 shows the principle of the ion implantation device with an energy filter as known in the prior art.

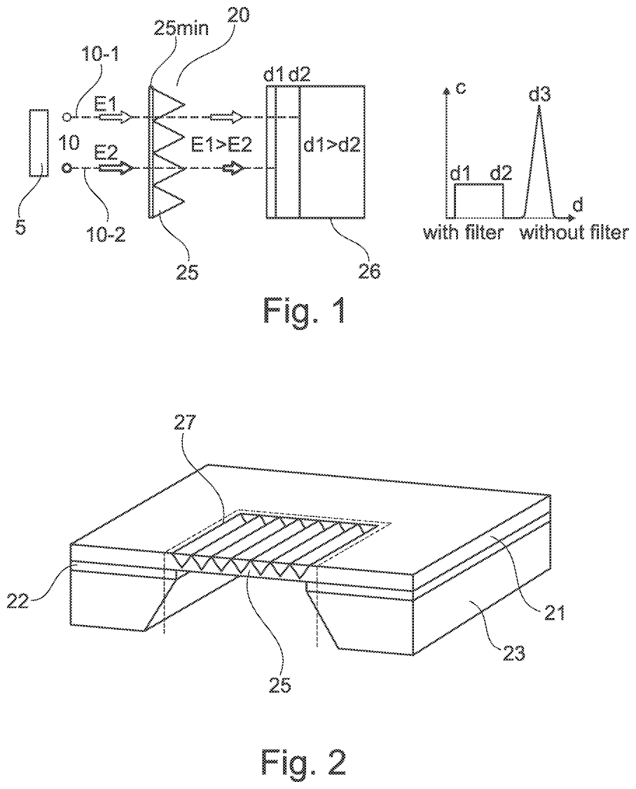

FIG. 2 shows a structure of the ion implantation device with the energy filter.

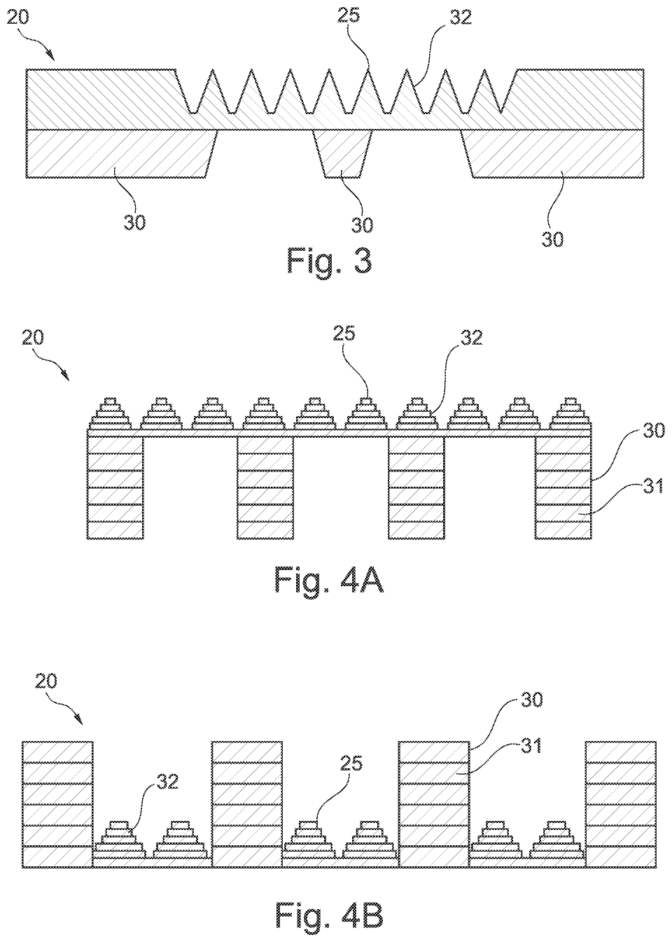

FIG. 3 shows a cross-section of an ion implantation device according to a first aspect of the present invention with an energy filter and at least one support element for supporting the energy filter.

FIG. 4A shows a cross-section of the ion implantation device according to the first aspect of the present invention with the at least one support element provided as a rear support element.

FIG. 4B shows a cross-section of the ion implantation device according to the first aspect of the present invention with the at least one support element provided as a front support element.

FIG. 4C shows a cross-section of the ion implantation device according to the first aspect of the present invention with a first height of the support element being at least the same as a maximal height of the energy filter.

FIGS. 5A to 5C show a top view of the at least one support element of the ion implantation device according to the first aspect of the present invention with an angled orientation with respect to the energy filter.

FIGS. 5D and 5E show a top view of ion implantation device according to the first aspect of the present invention with a different orientation.

FIGS. 6A to 6E show a top view of ion implantation device according to a second aspect of the present invention with a first energy filter having a first orientation and with a second energy filter having a second orientation, different than first orientation of the first energy filter.

FIGS. 7A to 7F show a flow diagram of methods for manufacturing the implantation devices according to the present invention.

### DETAILED DESCRIPTION OF THE INVENTION

The invention will now be described on the basis of the drawings. It will be understood that the embodiments and aspects of the invention described herein are only examples and do not limit the protective scope of the claims in any way. The invention is defined by the claims and their equivalents. It will be understood that features of one aspect or embodiment of the invention can be combined with a feature of a different aspect or aspects and/or embodiments of the invention. The object of the present invention is fully described below using examples for the purpose of disclosure, without limiting the disclosure to the examples. The examples present different aspects of the present invention. To implement the present technical teaching, it is not required to implement all of these aspects combined. Rather, a specialist will select and combine those aspects that appear sensible and required for the corresponding application and implementation.

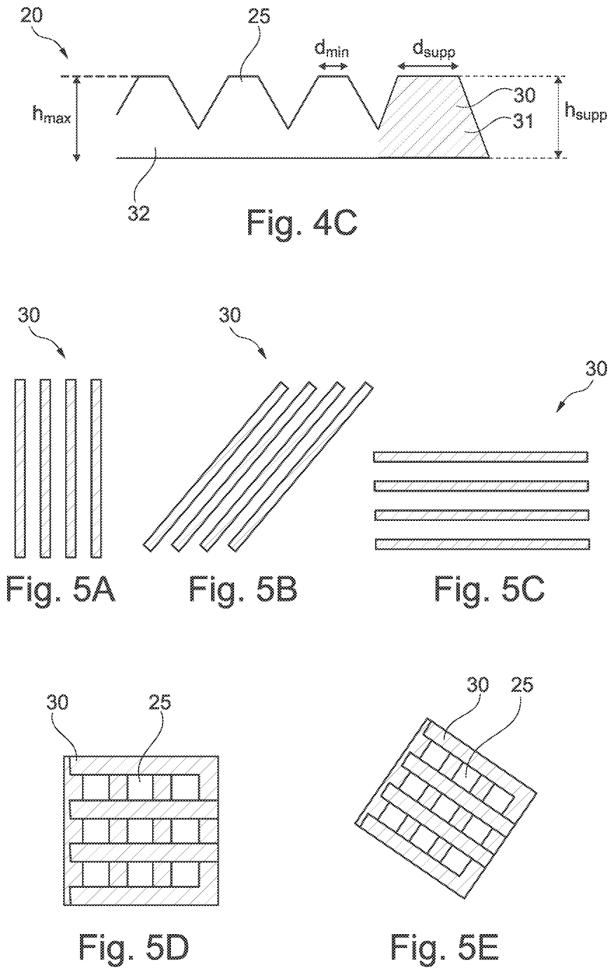

FIG. 3 shows a cross-section of an ion implantation device 20 according to a first aspect of the present invention with an energy filter 25 and at least one support element 30 for supporting at least part of the energy filter 25. The energy filter 25 is made from a membrane having a triangular cross-sectional form, but this type of cross-sectional form is not limiting of the present invention and other cross-sectional forms could be used.

The at least one support element 30 is made of silicon carbide, but the material of the support element 30 is not limiting of the present invention. The at least one support element 30 can be made of the same material or different material as the energy filter 25. In one non limiting example the energy filter 25 can be made from a single piece of material, for example, silicon on insulator which comprises an insulating layer silicon dioxide layer having, for example a thickness of 0.3-1.5 μm sandwiched between a silicon layer (of typical thickness between 2 and 20 μm, but up to 200 μm) and bulk silicon (around 400 μm or more thick).

The structured membrane is made, for example, from silicon, but could also be made from silicon carbide or another carbon-based material or a ceramic. The energy filter 25 has at least one filter layer 32 with a layer thickness having a minimum thickness of the membrane. As can be seen in FIG. 3, the at least one support element 30 is configured to support the energy filter 25, wherein the at least one support element 30 overlaps at least part of the energy filter When the at least one support element 30 overlaps at least part of the energy filter 25 the functionality of the energy filter 25 is disturbed in the overlapping area. The overlapping support element 30 creates an inactive area of at least part of the energy filter 25. In other words, the overlapping support element 30 leads to absorption of at least some of the energy of the ion beam 10 in the support element 30. The support element 30 has an absorption capacity equal or greater than the maximum absorption capacity of structural elements, i.e., the energy filter 25. Therefore, the overlapping support element 30 blocks or masks out the functionality of at least part of the energy filter 25 and the mechanical stability and thermomechanical stability of the energy filter 25 of the implantation device 20 is thereby improved.

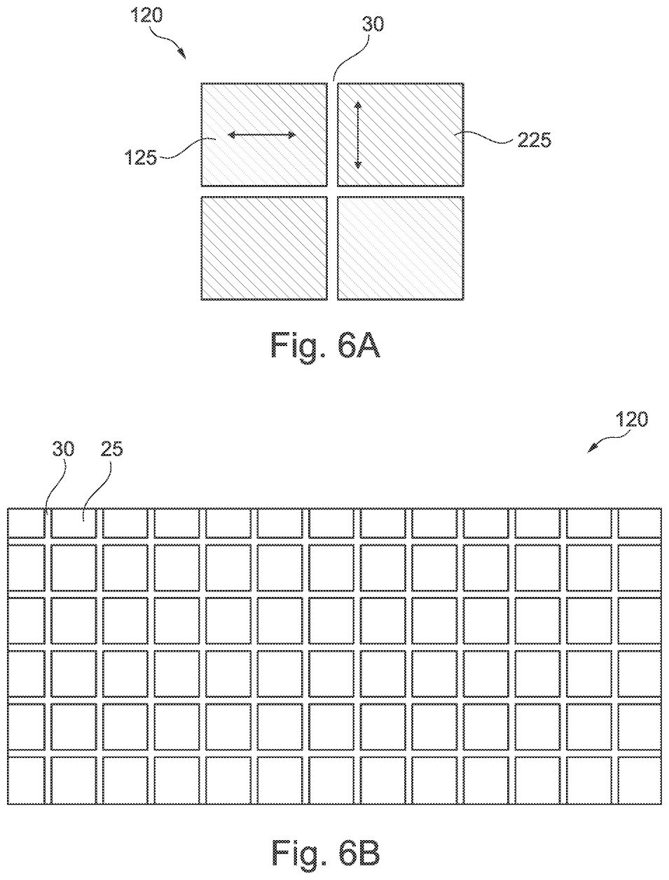

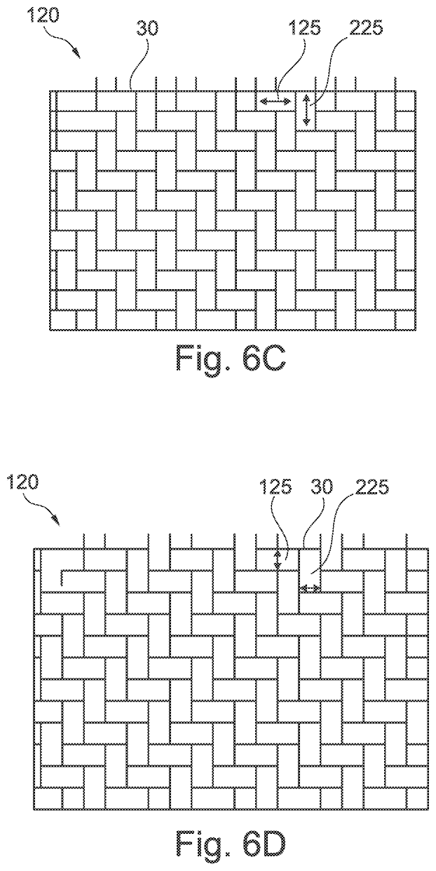

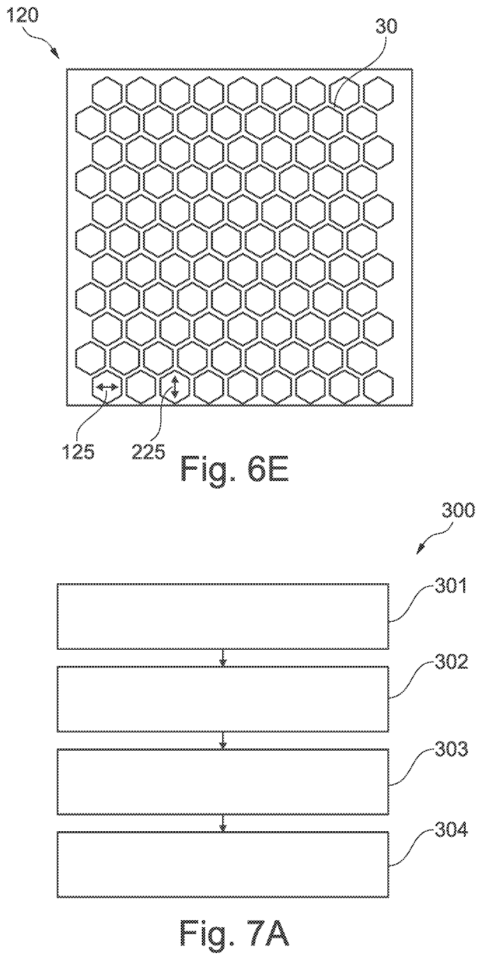

FIG. 4A shows a cross-section of the ion implantation device 20 according to the first aspect of the present invention with the at least one support element 30 provided as a rear support element. The energy filter 25 is made from a membrane having a triangular cross-sectional form having five filter layers 32 with each of the five filter layers 32 having a layer thickness with a minimum thickness of the membrane. The amount of filter layers and the shape of the resulting structure is not limiting of the present invention. As can be seen in FIG. 4A, the at least one support element 30 comprises a plurality of support layers 31. As can be seen in FIG. 4A, the at least one support element 30 comprises six support layers 31, but the amount of layers is not limiting of the present invention. Indeed, the at least one support element 30 can comprises up to 20 to 30 support layers 31. As can be seen in FIG. 4A, the at least one support element 30 is configured to support the energy filter 25, wherein the at least one support element overlaps at least part of the energy filter 25. FIG. 4B shows a cross-section of the ion implantation device 20 according to the first aspect of the present invention with the at least one support element 30 provided not in a rear support element but as a front support element.

The energy filter 25 including the support element 30 has different diameters. For 4″ (10.2 cm) diameter wafers: filters at least 5″ (12.7 cm) wide and up to 5″ (12.7 cm) high; For 6″ (15.2 cm) diameter wafers: filters at least 7″ (17.8 cm) wide and up to 7″ (17.8 cm) high; For 8″ (20.3 cm) diameter wafers: min. 9″ (22.9 cm) wide and up to 9″ (22.9 cm) high filters; For 12″ (30.5 cm) wafers: min. 13″ (33 cm) wide and up to 13″ (33 cm) high filters. The energy filter can have three shapes: Rectangular, e.g., 7″ (17.8 cm) wide and up to 6 cm high; Square, e.g., min. 13″×13″ (33 cm×33 cm); Round e.g. 7″ (33 cm) diameter. The at least one support element 30 has a thickness which value depends on technology. For a front support element design, the thickness of the support element 30 is the same as the energy filter 25 or the thickness of the support element 30 is greater than the energy filter 25. In the rear support element design, the support elements are preferably formed less than 100μm to a few mm.

FIG. 4C shows a cross-section of the ion implantation device 20 according to the first aspect of the present invention, wherein the support element 30 has a first height hsupp and the energy filter 25 has a maximal height hmax, wherein the first height hsupp of the support element is at least the same as the maximal height hmax of the energy filter 25. As can be seen in FIG. 4C, the at least one support element 30 is configured to support the energy filter 25, wherein the at least one support element 30 overlaps at least part of the energy filter 25 by providing the first height hsupp of the support element 30 being at least the same height as the maximal height hmax of the energy filter 25. When the at least one support element 30 with the first height hsupp overlaps at least part of the energy filter 25 the functionality of the energy filter 25 is disturbed in the overlapping area. The support element 30 has an absorption capacity equal or greater than the maximum absorption capacity of structural elements, i.e., the energy filter 25. In some cases of partial transparency of the energy filter 25, the overlapping support element with the first height hsupp creates an inactive area of at least a part of the energy filter 25. In other words, the overlapping support element 30 with the first height hsupp leads to absorption of at least some of the energy of the ion beam 10 in the support element 30. Therefore, in some cases of partial transparency of the energy filter 25, the overlapping support element 30 with the first height hsupp blocks or masks out the functionality of at least part of the energy filter 25. The support element 30 of a fully transparent energy filter 25 will add discrete peaks to a preferred smooth (continuous) profile. In any case, if the primary energy is high enough, the supporting element 30 also contributes to the resulting depth profile in the substrate. This contribution consists of a discrete energy, which contributes to the total dose of the profile according to the area fraction on the energy filter 25. The mechanical stability and thermomechanical stability of the energy filter 25 of the implantation device 20 is thereby improved.

As can also be seen in the cross sectional view of FIG. 4C, the support element 30 of the ion implantation device 20 according to the first aspect of the present invention has a first width dₛᵤₚₚ and the energy filter 25 has a minimal width dₘᵢₙ, wherein the first width dₛᵤₚₚ of the support element 30 is at least the same as the minimal width dₘᵢₙ of the energy filter 25, wherein dₘᵢₙ of the energy filter 25 is provided as a plateau and is the technological minimum width of the energy filter 25. In one aspect of the present invention, the minimal width dₘᵢₙ (technological minimum width) of the energy filter 25 is +/−0,3 μm, +/−0,5 μm, or +/−0,8 μm, but the minimal width dₘᵢₙ is not limiting of the present invention. In another aspect of the present invention, the first width dₛᵤₚₚ of the support element 30 is at least 10%, 20% or 50% larger than the minimal width dₘᵢₙ of the energy filter 25. In particular, in yet another aspect of the present invention, the first width dₛᵤₚₚ of the support element 30 is at least two, five or ten times larger than the minimal width dₘᵢₙ of the energy filter 25. As can be seen in FIG. 4C, the at least one support element 30 is configured to support the energy filter 25, wherein the at least one support element 30 overlaps at least part of the energy filter 25 by providing the first width dₛᵤₚₚ of the support element 30 with a width being at least the same as the minimal width dₘᵢₙ of the energy filter 25. The support element 30 has an absorption capacity equal or greater than the maximum absorption capacity of structural elements, i.e., the energy filter 25. In some cases of partial transparency of the energy filter 25, when the at least one support element 30 with the first width dₛᵤₚₚ overlaps at least part of the energy filter 25 the functionality of the energy filter 25 is disturbed in the overlapping area. Therefore, in some cases of partial transparency of the energy filter 25, the overlapping support element 30 with the first width dₛᵤₚₚ creates an inactive area of the energy filter 25. In other words, the overlapping support element 30 with the first width dₛᵤₚₚ leads to absorption of at least some of the energy of the ion beam 10 in the support element 30. Therefore, in some cases of partial transparency of the energy filter 25, the overlapping support element 30 with the first width dₛᵤₚₚ blocks or masks out the functionality of at least part of the energy filter 25. The support element 30 of a fully transparent energy filter will add discrete peaks to a preferred smooth (continuous) profile. In any case, if the primary energy is high enough, the supporting element 30 also contributes to the resulting depth profile in the substrate. This contribution consists of a discrete energy, which contributes to the total dose of the profile according to the area fraction on the energy filter 25. The mechanical stability and thermomechanical stability of the energy filter 25 of the implantation device 20 is thereby improved.

As can be seen in FIG. 4C, the at least one support element 30 is defined in such a way that the first width dₛᵤₚₚ of the at least one support element 30 is larger than a manufacturing plateau area dₘᵢₙ. The manufacturing plateau area dₘᵢₙ is determined by the applied etching and lithography process. Typical values of the manufacturing plateau area dₘᵢₙ are e.g., 0.3 μm, 0.5 μm or 0.8 μm. In order to optimize the transparency of the energy filter 25, the value of the manufacturing plateau area dₘᵢₙ is chosen to be as small as possible. The at least one support element 30 is defined by exceeding these minimum values, the wider the at least one support element 30, the greater is the mechanical stability and the thermomechanical stability of the energy filter 25.

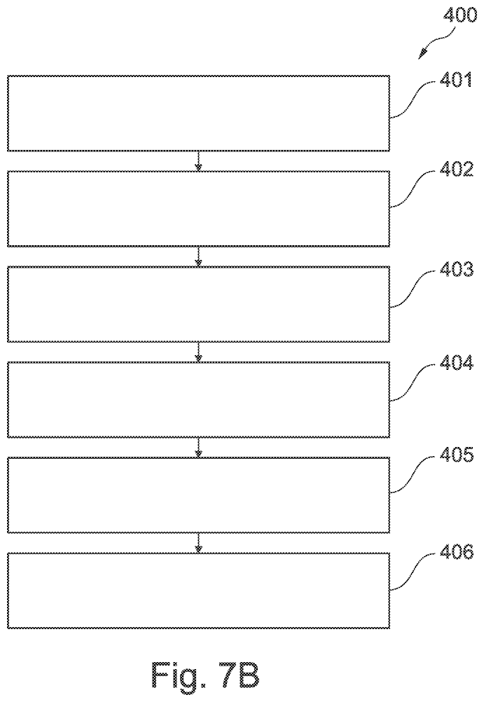

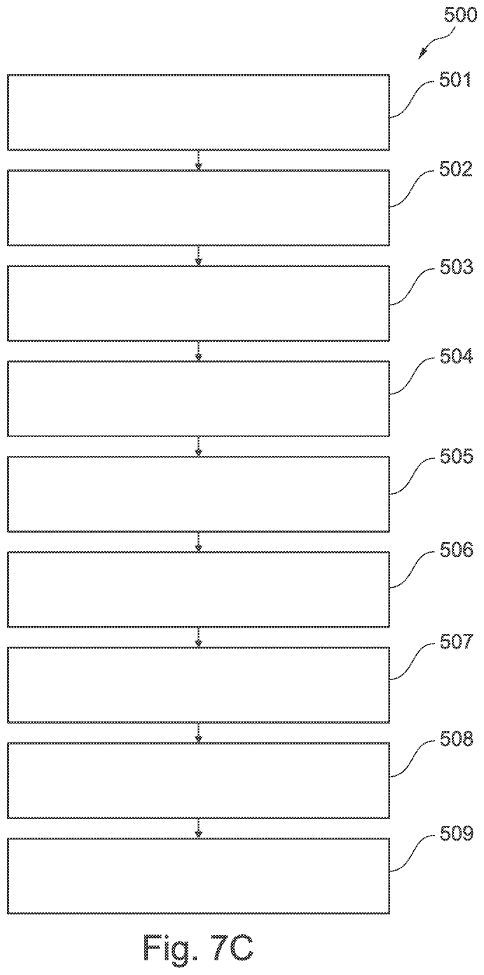

FIGS. 5A to 5C show a top view of the at least one support element 30 of the ion implantation device 20 according to the first aspect of the present invention with an angled orientation of the support element 30 with respect to the energy filter 25. By providing the angled orientation of the support element 30 with respect to the energy filter 25, the mechanical stability and thermomechanical stability of the energy filter 25 of the implantation device 20 is further improved.

FIGS. 5D and 5E show a top view of ion implantation device 20 according to the first aspect of the present invention with a different orientation. As can be seen in FIG. 5D, the at least one support element 30 is configured to support the energy filter 25, wherein the at least one support element 30 overlaps at least part of the energy filter 25. The support element 30 has an absorption capacity equal or greater than the maximum absorption capacity of structural elements, i.e., the energy filter 25. In some cases of partial transparency of the energy filter 25, when the at least one support element 30 overlaps at least part of the energy filter 25 the functionality of the energy filter 25 is disturbed in the overlapping area. In some cases of partial transparency of the energy filter 25, the overlapping support element 30 creates an inactive area of at least part of the energy filter 25. In other words, in some cases of partial transparency of the energy filter 25, the overlapping support element 30 leads to absorption of at least some of the energy of the ion beam 10 in the support element 30. Therefore, in some cases of partial transparency of the energy filter 25, the overlapping support element 30 is blocking or masking out the functionality of at least part of the energy filter. The support element 30 of a fully transparent energy filter 25 will add discrete peaks to a preferred smooth (continuous) profile. In any case, if the primary energy is high enough, the supporting element 30 also contributes to the resulting depth profile in the substrate. This contribution consists of a discrete energy, which contributes to the total dose of the profile according to the area fraction on the energy filter 25. The mechanical stability and thermomechanical stability of the energy filter 25 of the implantation device 20 is thereby improved. As can be seen in FIG. 5E, the ion implantation device 20 has a different orientation with respect to the ion beam source 5 (not shown) compared to the ion implantation device 20 shown in FIG. 5D. By providing a different orientation with respect to the ion beam source 5, the mechanical stability and thermomechanical stability of the energy filter 25 of the implantation device 20 is further improved.

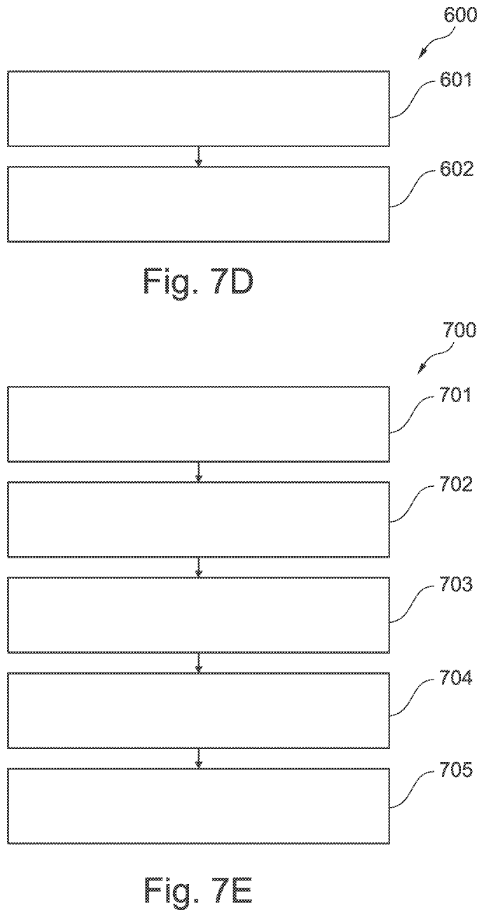

FIGS. 6A to 6E show a top view of ion implantation device 120 according to a second aspect of the present invention with a first energy filter 125 having a first orientation and with a second energy filter 225 having a second orientation. The second orientation is different than the first orientation of the first energy filter 125. The ion implantation device 120 according to the second aspect of the present invention comprises the first energy filter 125 having the first orientation and the second energy filter 225 having the second orientation. The ion implantation device 120 further comprises at least one support element 30 for supporting the first energy filters 125 and second energy filters 225, wherein the at least one support element 30 is overlapping at least part of the first energy filters 125 and at least part of second energy filters 225. The first orientation of the first energy filter 125 is different from the second orientation of the second energy filter 225.

As can be seen in FIG. 6A, the weak points between the abutting first energy filter 125 and the second energy filter 225 both in a horizontal and vertical direction with respect to a top view of the ion implantation device 120 is solved by providing at least one support element 30 for supporting the first energy filters 125 and second energy filters 225, wherein the at least one support element 30 overlaps at least part of the first energy filters 125 and at least part of second energy filters 225, and wherein the first orientation of the first energy filter 125 is different from the second orientation of the second energy filter 225. As can be seen in FIGS. 6C and 6D, the weak points between the abutting first energy filter 125 and the second energy filter 225 can be solved by a chessboard arrangement of the ion implantation device 120 having a high stability both mechanically and thermomechanically. As can be seen in FIG. 6E, the weak points between the abutting first energy filter 125 and the second energy filter 225 can be solved by a honeycomb arrangement of the ion implantation device 120 having a high stability both mechanically and thermomechanically.

The first energy filter 125 and the second energy filter 225 of the ion implantation device 120 according to the second aspect of the present invention are made from a membrane having a triangular cross-sectional form, but this type of cross-sectional form is not limiting of the present invention and other cross-sectional forms could be used. The at least one support element 30 of the ion implantation device 120 according to the second aspect of the present invention is made of silicon carbide, but the material of the support element 30 is not limiting of the present invention. The at least one support element 30 can be made of the same material or different material as the first energy filter 125 and the second energy filters 225. In one non limiting example the first energy filter 125 and the second energy filter 225 can be made from a single piece of material, for example, silicon on insulator which comprises an insulating layer silicon dioxide layer having, for example a thickness of 0.2-1 μm sandwiched between a silicon layer (of typical thickness between 2 and 20 μm, but up to 200 μm) and bulk silicon (around 400 μm thick). The structured membrane is made, for example, from silicon, but could also be made from silicon carbide or another carbon-based material or a ceramic. The first and second energy filters 125, 225 have at least one filter layer 32 with a layer thickness having a minimum thickness of the membrane.

As can be seen in FIGS. 6A to 6E, the at least one support element 30 is configured to support the first energy filter 125 and the second energy filter 225, wherein the at least one support element 30 overlaps at least part of the first energy filter 125 and at least part of the second energy filters 225. The support element 30 has an absorption capacity equal or greater than the maximum absorption capacity of structural elements, i.e., the first energy filter 125 and the second energy filter 225. In some cases of partial transparency of the first energy filter 125 and the second energy filter 225, when the at least one support element 30 overlaps at least part of the first energy filter 125 and at least part of the second energy filter 225, the functionality of the first energy filter 125 and the second energy filter 225 is disturbed in the overlapping area. In some cases of partial transparency of the first energy filter 125 and the second energy filter 225, the overlapping support element 30 creates an inactive area of at least part of the first energy filter 125 and at least part of the second energy filter 225. In other words, in some cases of partial transparency of the first energy filter 125 and the second energy filter 225, the overlapping support element 30 leads to absorption of at least some of the energy of the ion beam 10 in the support element 30. Therefore, in some cases of partial transparency of the first energy filter 125 and the second energy filter 225, the overlapping support element 30 blocks or masks out the functionality of at least part of the first energy filter 125 and at least part of the second energy filter 225. The support element 30 of a fully transparent first energy filter 125 and second energy filter 225 will add discrete peaks to a preferred smooth (continuous) profile. In any case, if the primary energy is high enough, the supporting element 30 also contributes to the resulting depth profile in the substrate. This contribution consists of a discrete energy, which contributes to the total dose of the profile according to the area fraction on the first energy filter 125 and second energy filter 225. Thereby, overall mechanical stability and thermomechanical stability of the first energy filter 125 and the second energy filter 225 of the implantation device 120 can be further improved.

As can be seen in FIGS. 6A to 6E, the first energy filter 125 and the second energy filter 225 are arranged in one of a square composite arrangement, a rectangular composite arrangement, a hexagonal composite arrangement or a cross-network composite arrangement. The mechanical stability and thermomechanical stability of the first energy filter 125 and the second energy filter 225 of the implantation device 120 is thereby improved.

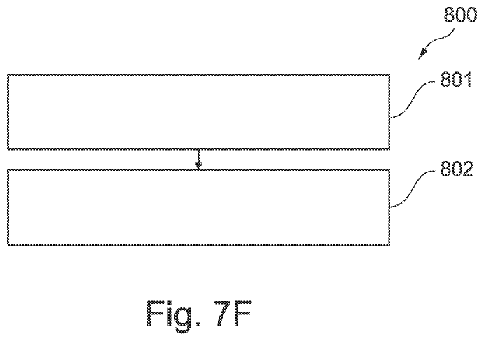

FIGS. 7A to 7F show a flow diagram of methods for manufacturing the implantation devices 20, 120 according to the present invention.

According to a third aspect of the present invention, a method 300 for manufacturing an ion implantation device 20 according to the first aspect of the present invention is provided. The method comprises the steps of: Providing 301 an energy filter 25 with at least one filter layer 32; Providing 302 at least one support element 30; Supporting 303 the energy filter 25 by the at least one support element 30; and overlapping 304 at least part of the energy filter 25 by the at least one support element 30. The support element 30 has an absorption capacity equal or greater than the maximum absorption capacity of structural elements, i.e., the energy filter 25. In some cases of partial transparency of the energy filter 25, when the at least one support element 30 overlapping at least part of the energy filter 25 the functionality of the energy filter is disturbed in the overlapping area. In some cases of partial transparency of the energy filter 25, the overlapping support element 30 creates an inactive area of at least part of the energy filter 25. In other words, in some cases of partial transparency of the energy filter 25, the overlapping support element 30 leads to absorption of at least some of the energy of the ion beam 10 in the support element 30. Therefore, in some cases of partial transparency of the energy filter 25, the overlapping support element 30 blocks or masks out the functionality of at least part of the energy filter 25. The support element 30 of a fully transparent energy filter 25 will add discrete peaks to a preferred smooth (continuous) profile. In any case, if the primary energy is high enough, the supporting element 30 also contributes to the resulting depth profile in the substrate. This contribution consists of a discrete energy, which contributes to the total dose of the profile according to the area fraction on the energy filter 25. The mechanical stability and thermomechanical stability and thermomechanical stability and thermomechanical stability of the energy filter 25 of the implantation device 20 is thereby improved.

According to a fourth aspect of the present invention, a method 400 for manufacturing an ion implantation device 120 according to the second aspect of the present invention is provided. The method comprises the steps of: Providing 401 a first energy filter 125; Orientating 402 the first energy filter 125 in a first orientation; Providing 403 a second energy filter 225; Orientating 404 the second energy filter 225 in a second orientation different to the first orientation of the first energy filter 125; Supporting 405 the first and second energy filters 125, 225 by the at least one support element 30; and overlapping 406 at least part of the first energy filter 125 and at least part of second energy filter 225 by the at least one support element The support element 30 has an absorption capacity equal or greater than the maximum absorption capacity of structural elements, i.e., the first energy filter 125 and second energy filter 225. In some cases of partial transparency of the first energy filter 125 and second energy filter 225, when the at least one support element 30 overlapping at least part of the first energy filter 125 and at least part of second energy filter 225, the functionality of the first and second energy filters 125, 225 is disturbed in the overlapping area. In some cases of partial transparency of the first energy filter 125 and second energy filter 225, the overlapping support element 30 creates an inactive area of at least part of the first energy filter 125 and second energy filter 225. In other words, in some cases of partial transparency of the first energy filter 125 and second energy filter 225, the overlapping support element 30 leads to absorption of at least some of the energy of the ion beam 10 in the support element 30. Therefore, in some cases of partial transparency of the first energy filter 125 and second energy filter 225, the overlapping support element 30 is blocking or masking out the functionality of at least part of the first energy filter 125 and at least part of second energy filter 225. The support element 30 of a fully transparent first energy filter 125 and second energy filter 225 will add discrete peaks to a preferred smooth (continuous) profile. In any case, if the primary energy is high enough, the supporting element also contributes to the resulting depth profile in the substrate. This contribution consists of a discrete energy, which contributes to the total dose of the profile according to the area fraction on the first energy filter 125 and second energy filter 225. The overall mechanical stability and thermomechanical stability of the first energy filter 125 and the second energy filter 225 of the implantation device 120 can be further improved.

In a further aspect, the method 300, 400 for manufacturing an ion implantation device 20, 120 of the third or fourth aspect of the present invention can be used in one of a screen printing, multi-layer process, lithography patterning process and etching process sequence.

According to a fifth aspect of the present invention, a method 500 for manufacturing an ion implantation device 20, 120 according to the first and second aspects of the present invention comprising the steps of: Providing 501 a silicon-on-insulator (SOI) wafer as a substrate material having a first surface and a second surface, wherein the thickness of a buried oxide (BOX) varies between 30 nm and 1.5 μm thickness; Applying 502 a first masking material layer and a second masking material layer for masking wet chemical potassium hydroxide (KOH) etching or tetramethylammonium hydroxide (TMAH) etching to the first surface and the second surface of the SOI wafer; Patterning 503 the first masking material layer and the second masking material layer on the first surface and the second surface by using a first and second lithography process step and at least one wet or dry etching patterning step; Cleaning 504 of the first and second surfaces after patterning of the masking material layers; First wet chemical etching 505 of the first or second surfaces using KOH or TMAH etchant; Second wet chemical etching 506 of the first or the second surface using KOH or TMAH etchant; Wet chemical etching 507 of the first or the second surface such that etching is stopped on the BOX layer; Removing 508 of the BOX layer; and removing 509 of the masking layers on the first and second surfaces.

In one aspect of the method 500, a first protective layer is applied to the first surface or the second surface to prevent etching. In one further aspect of the method 500, a second protective layer is applied to the first or the second surface to prevent etching of the first or the second surface.

In one aspect of the method 500, typical SOI-layer thicknesses are 6 μm, 10 μm, 17 μm, 25 μm, 50 μm or 100 μm.

In one aspect of the method 500, after hard mask formation, a protective layer is applied to the frontside and backside etching is performed first. Then protective layer is removed. A protective layer is deposited on the backside. Frontside KOH or TMAH etching is performed. Removal of all masking and protective layers and BOX layer.

In one aspect of the method 500, for example, if a maximal profile length in silicon is chosen as 16 μm, then the SOI layer is chosen as 16 μm+base layer i.e., 300 nm up to 1000 nm. If the target implantation material is a material other than silicon, the mismatch in stopping power as a function of ion energy has to be taken into account and the required SOI layer thickness needs to be rescaled accordingly.

According to a sixth aspect of the present invention, a method 600 for manufacturing an ion implantation device 20, 120 according to the first and second aspect of the present invention comprising the steps of: Providing 601 a volume material slab, wherein the thickness of the volume material slab is at least the height of a support element 30; and Sequentially removing 602 of the material by a laser etching or mechanical erosive device, wherein the removing 602 is incremental several 1 Onm up to several micrometer per step and involves several removal steps for a given structure, and wherein the sequentially removing is performed according to a predefined 3-D layout of an energy filter 25, 125 structure and supporting elements 30.

In one aspect of the method 600, a volume material slab of suitable size (circular or square or rectangular from 2×2 cm up to 40×40 cm) is provided, where the thickness of the material slab is at least hsupp plus a thickness of the at least one support element 30. The material slab is made of silicon, silicon carbide, glass, glass-like material or carbon.

In one aspect of the method 600, optionally grinding/etching of base layer to desired final thickness can be provided if desired and/or needed.

According to a seventh aspect of the present invention, a method 700 for manufacturing an ion implantation device 20, 120 according to the first and second aspect of the present invention comprising the steps of: Providing 701 a substrate or base layer; Depositing 702 a first support layer 31 and a first filter layer 32; Patterning 702 the first support layer 31 and the first filter layer 32 using suitable etching techniques like masked etching or sequential etching by a laser or ion beam etching device; Depositing and patterning sequentially multiples of first support layers 31 and the first filter layers 32; and removing, grinding or etching the substrate or base layer to a desired substrate layer thickness or base layer thickness.

In one aspect of the method 700, a substrate or base layer of suitable size (circular or square or rectangular from 2×2 cm up to 40×40 cm) is provided.

In one aspect of the method 700, the layer is patterned after deposition using suitable etching techniques like masked etching (photolithography and wet- or dry etching) or sequential etching by a laser or ion beam etching device. Alternatively, the layer is patterned during deposition, e.g., by a screen printing or moulding or imprint patterning process. Thickness of deposited layers is between several 100 nm and several micrometer. Manufacturing may involve sintering steps after each deposition step or after multiples of deposition steps. The layer material is silicon, silicon carbide, glass, glass-like material or carbon. The layer material is a dense material or a material containing voids (10% or 30% or 50% of voids). The layer material of 32 may differ from material for layer 31. Thickness of deposited layers also may be differing between layer 32 and 31. Substrate is removed or substrate is grinded/etched to a desired base layer thickness.

According to an eighth aspect of the invention, a method 800 for manufacturing an ion implantation device 20, 120 according to the first and second aspect of the present invention comprising the steps of: Providing 801 an energy filter 25, 125 and a separate structure of supporting elements 30; and applying 802 a bonding layer or gluing layer to achieve a permanent, thermomechanically stable connection between the energy filter 25, 125 and the supporting elements 30.

It is possible that the energy filter 25, 125 are periodically provided with supporting elements 30 on the rear or the front. These supporting elements 30 are characterized by the fact that they are for example formed from the substrate wafer material and are designed as rectangular or square grid. The arrangement of the triangular-shaped energy filter elements 25, 125 on the front are configured such that all trench elements are arranged parallel to each other. In the present invention the individual elements of trench-shaped energy filter elements 25, 125 both “horizontally” and “vertically” or at any angle to each other. In this way, the surface of an energy filter element 25, 125 disintegrates into individual elements that can be arranged in any desired way to each other.

### REFERENCE NUMERALS

5 Ion beam source
10 Ion Beam
20 Ion implementation device
21 Silicon layer
22 Silicon dioxide layer
23 Bulk silicon
25 Energy Filter
27 Filter Frame
26 Substrate material
30 Support element
31 Support layer
32 Filter layer
120 Ion implementation device
125 First energy filter
225 Second energy filter

1. An ion implantation device comprising:
an energy filter with at least one filter layer; and
at least one support element for supporting the energy filter, wherein the at least one support element overlaps at least part of the energy filter, wherein the at least one support element has a first height and the energy filter has a maximal height wherein the first height of the at least one support element is at least the same as the maximal height of the energy filter, and wherein the at least one support element has a first width and the energy filter has a minimal width, wherein the first width of the at least one support element is at least the same as the minimal width of the energy filter.

2. The ion implantation device of claim 1, wherein the at least one support element is a rear support element.

3. The ion implantation device of claim 1, wherein the at least one support element is a front support element.

4. The ion implantation device of claim 1, wherein the at least one support element comprises at least one support layer.

5. (canceled)

6. (canceled)

7. The ion implantation device of claim 1, wherein the minimal width of the energy filter is +/−0,3 μm, +/−0,5 μm, or +/−0,8 μm.

8. The ion implantation device of claim 6, wherein the first width of the at least one support element is at least 10%, 20% or 50% larger than the minimal width of the energy filter.

9. The ion implantation device of claim 1, wherein the first width of the at least one support element is at least two, five or ten times larger than the minimal width of the energy filter.

10. The ion implantation device of claim 1, wherein the at least one support element is made of silicon carbide.

11. The ion implantation device of claim 1, wherein the at least one support element is made of the same material as the energy filter.

12. The ion implantation device of claim 1, wherein the at least one support element is made of a different material as the energy filter.

13. The ion implantation device of claim 1, wherein the at least one support element has an absorption capacity equal or greater than the maximum absorption capacity of the energy filter.

14. An ion implantation device comprising:
a first energy filter with a first orientation;
a second energy filter with a second orientation; and
at least one support element for supporting the first and second energy filter, wherein the at least one support element is overlapping at least part of the first energy filter and at least part of second energy filter, and wherein the first orientation of the first energy filter is different from the second orientation of the second energy filter.

15. The ion implantation device of claim 14, wherein the first energy filter and the second energy filter are arranged in one of a square composite arrangement, a rectangular composite arrangement, a hexagonal composite arrangement or a cross-network composite arrangement.

16. The ion implantation device of claim 14, wherein the at least one support element has an absorption capacity equal or greater than the maximum absorption capacity of the first energy filter and the second energy filter.

17. A method for manufacturing an ion implantation device, comprising the steps of:
providing an energy filter with at least one filter layer;
providing at least one support element;
supporting the energy filter by the at least one support element; and
Overlapping at least part of the energy filter by the at least one support element.

18. A method for manufacturing an ion implantation device, comprising the steps of:
providing a first energy filter;
orientating the first energy filter in a first orientation;
providing a second energy filter;
orientating the second energy filter in a second orientation different to the first orientation of the first energy filter;
supporting the first and second energy filters by the at least one support element; and
overlapping at least part of the first energy filter and at least part of the second energy filter by the at least one support element.

19. Use of the method for manufacturing an ion implantation device of claim 1 in one of a screen printing, multi-layer process, lithography patterning process and etching process sequence.

20. A method for manufacturing an ion implantation device, comprising the steps of:
providing a silicon-on-insulator (SOI) wafer as a substrate material having a first surface and a second surface, wherein the thickness of a buried oxide (BOX) varies between 30 nm and 1.5 μm thickness;
applying a first masking material layer and a second masking material layer for masking wet chemical potassium hydroxide (KOH) etching or tetramethylammonium hydroxide (TMAH) etching to the first surface and the second surface of the SOI wafer;
patterning the first masking material layer and the second masking material layer on the first surface and the second surface by using a first and second lithography process step and at least one wet or dry etching patterning step;
cleaning of the first and second surfaces after patterning of the masking material layers;
first wet chemical etching of the first or second surfaces using KOH or TMAH etchant;
second wet chemical etching of the first or the second surface using KOH or TMAH etchant;
wet chemical etching of the first or the second surface such that etching is stopped on the BOX layer;
removing of the BOX layer; and
removing of the masking layers on the first and second surfaces.

21. The method of claim 20, applying a first protective layer to the first surface or the second surface to prevent etching.

22. The method of claim 20, applying a second protective layer to the first or the second surface to prevent etching of the first or the second surface.

23. A method for manufacturing an ion implantation device, comprising the steps of:
providing a volume material slab, wherein the thickness of the volume material slab is at least of the height of at least one support element; and
sequentially removing of the material by a laser etching or mechanical erosive device, wherein the removing is incremental several 10 nm up to several micrometer per step and involves several removal steps for a given structure, and wherein the sequentially removing is performed according to a predefined 3-D layout of an energy filter structure and the at least one supporting element.

24. A method for manufacturing an ion implantation device, comprising the steps of:
providing a substrate or base layer;
depositing a first support layer and a first filter layer;
patterning the first support layer and the first filter layer using suitable etching techniques like masked etching or sequential etching by a laser or ion beam etching device;
depositing and patterning sequentially multiples of first support layers and the first filter layers; and
removing, grinding or etching the substrate or base layer to a desired substrate layer thickness or base layer thickness.

25. A method for manufacturing an ion implantation device, comprising the steps of:
providing an energy filter and a separate structure of at least one support element; and
applying a bonding layer or gluing layer to achieve a permanent, thermomechanically stable connection between the energy filter and the at least one support element.

26. Use of the method for manufacturing an ion implantation device of claim 14 in one of a screen printing, multi-layer process, lithography patterning process and etching process sequence.
